(19) United States
(12) Patent Application Publication
(10) Pub. No.: US 2024/0334767 A1
(43) Pub. Date: Oct. 3, 2024

(54) DISPLAY DEVICE

(71) Applicant: Japan Display Inc., Tokyo (JP)

(72) Inventor: Shinichi KAWAMURA, Tokyo (JP)

(73) Assignee: Japan Display Inc., Tokyo (JP)

(21) Appl. No.: 18/588,013

(22) Filed: Feb. 27, 2024

(30) Foreign Application Priority Data
Mar. 29, 2023 (JP) 2023-053377

(51) Int. Cl. H10K 59/131; H10K 59/126; H10K 59/80; H10K 102/10

(52) U.S. Cl. CPC H10K 59/131; H10K 59/126; H10K 59/879; H10K 2102/103

(57) ABSTRACT

According to one embodiment, a display device includes a lower electrode, a rib having a pixel aperture, a partition including a conductive bottom portion, an insulating stem portion, and a top portion, an organic layer which covers the lower electrode through the pixel aperture, and an upper electrode which covers the organic layer and is in contact with the bottom portion. Further, the partition includes a first portion in which the bottom portion having a first thickness, the stem portion and the top portion are stacked, and a second portion in which the bottom portion having a second thickness less than the first thickness, the stem portion and the top portion are stacked.

### CROSS-REFERENCE TO RELATED APPLICATION

This application is based upon and claims the benefit of priority from Japanese Patent Application No. 2023-053377, filed Mar. 29, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer.

In a display area in which a plurality of display elements are provided, lines for supplying electricity to upper electrodes are formed. The resistance by these lines needs to be adjusted so as to be an appropriate value. However, this adjustment is not necessarily easy in terms of the structure of the display elements and the vicinity of the display elements.

In addition, translucency is required in some display devices. However, if the above lines are formed of a material having light-shielding properties such as metal, the translucency of the display device could be considerably decreased.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a schematic cross-sectional view showing an example of a configuration which could be applied to the first and second portions of a partition in the first embodiment.

FIG. 5 is a schematic cross-sectional view showing another example of a configuration which could be applied to the first and second portions of the partition in the first embodiment.

FIG. 6 is a schematic cross-sectional view showing yet another example of a configuration which could be applied to the first and second portions of the partition in the first embodiment.

FIG. 7 is a diagram showing an implementation example of the partition and a rib in the first embodiment.

FIG. 8 is a flowchart showing an example of the manufacturing method of the display device.

FIG. 9 is a diagram showing a process for forming the rib and the partition in the first embodiment.

FIG. 10 is a diagram showing a process following FIG. 9.

FIG. 11 is a diagram showing a process following FIG. 10.

FIG. 12 is a diagram showing a process following FIG. 11.

FIG. 13 is a diagram showing a process following FIG. 12.

FIG. 14 is a diagram showing a process following FIG. 13.

FIG. 15 is a schematic cross-sectional view showing a process for forming a display element in the first embodiment.

FIG. 16 is a diagram showing a process following FIG. 15.

FIG. 17 is a diagram showing a process following FIG. 16.

FIG. 18 is a diagram showing a process following FIG. 17.

FIG. 19 is a diagram showing a process following FIG. 18.

FIG. 20 is a diagram showing a process following FIG. 19.

FIG. 21 is a diagram showing an example of a use situation of the display device.

FIG. 22 is a schematic cross-sectional view showing an example of a partition in a second embodiment.

FIG. 23 is a diagram showing an implementation example of the partition and a rib in the second embodiment.

FIG. 24 is a diagram showing a process for forming the rib and the partition in the second embodiment.

FIG. 25 is a diagram showing a process following FIG. 24.

FIG. 26 is a diagram showing a process following FIG. 25.

FIG. 27 is a diagram showing a process following FIG. 26.

FIG. 28 is a diagram showing a process following FIG. 27.

FIG. 29 is a diagram showing an implementation example of a partition and a rib in a third embodiment.

### DETAILED DESCRIPTION

In general, according to one embodiment, a display device comprises a lower electrode, a rib having a pixel aperture which overlaps the lower electrode, a partition comprising a conductive bottom portion provided on the rib, an insulating stem portion provided on the bottom portion, and a top portion provided on the stem portion and protruding from a side surface of the stem portion, an organic layer which covers the lower electrode through the pixel aperture and emits light based on application of voltage, and an upper electrode which covers the organic layer and is in contact with the bottom portion.

According to an aspect of the embodiment, the partition includes a first portion in which the bottom portion having a first thickness, the stem portion and the top portion are stacked, and a second portion in which the bottom portion having a second thickness less than the first thickness, the stem portion and the top portion are stacked.

According to another aspect of the embodiment, the partition includes a first portion in which the bottom portion, the stem portion and the top portion are stacked, and a second portion in which the stem portion and the top portion are stacked, and the bottom portion is not provided under the stem portion.

According to yet another aspect of the embodiment, the rib, the bottom portion, the stem portion and the top portion have translucency.

The embodiments can provide a display device comprising an improved interconnection structure.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. The third direction Z is a normal direction relative to a plane including the first direction X and the second direction Y. When various elements are viewed parallel to the third direction Z, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

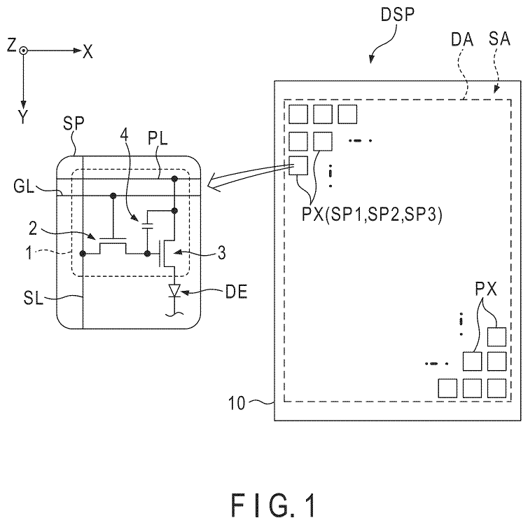

FIG. 1 is a diagram showing a configuration example of a display device DSP according to a first embodiment. The display device DSP comprises a display area DA which displays an image and a surrounding area SA around the display area DA on an insulating substrate 10. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes a blue subpixel SP1, a green subpixel SP2 and a red subpixel SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

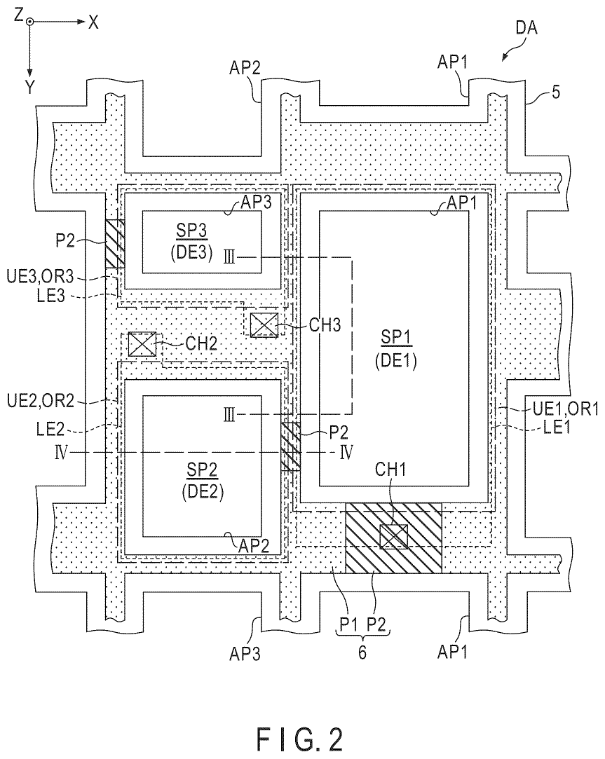

FIG. 2 is a schematic plan view showing an example of the layout of subpixels SP1, SP2 and SP3. In the example of FIG. 2, each of subpixels SP2 and SP3 is adjacent to subpixel SP1 in the first direction X. Further, subpixels SP2 and SP3 are arranged in the second direction Y.

When subpixels SP1, SP2 and SP3 are provided in line with this layout, in the display area DA, a column in which subpixels SP2 and SP3 are alternately provided in the second direction Y and a column in which a plurality of subpixels SP1 are repeatedly provided in the second direction Y are formed. These columns are alternately arranged in the first direction X. It should be noted that the layout of subpixels SP1, SP2 and SP3 is not limited to the example of FIG. 2.

A rib 5 and a partition 6 are provided in the display area DA. The rib 5 comprises pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3.

The partition 6 is provided in the boundary between adjacent subpixels SP and overlaps the rib 5 as seen in plan view. In the example of FIG. 2, the partition 6 has a grating shape surrounding the pixel apertures AP1, AP2 and AP3. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 and the partition 6 surround each of these display elements DE1, DE2 and DE3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3. In the example of FIG. 2, the contact holes CH1, CH2 and CH3 overlap the rib 5 and the partition 6 as a whole. However, the configuration is not limited to this example.

The partition 6 divides the display elements DE1, DE2 and DE3 from each other and functions as lines for supplying electricity to the upper electrodes UE1, UE2 and UE3. In the embodiment, the partition 6 comprises a first portion P1 and a plurality of second portions P2. The first portion P1 is the area shown by the dotted pattern in FIG. 2. The second portions P2 are the areas shown by the diagonal pattern in FIG. 2. The first portion P1 is conductive.

Electricity is supplied to the upper electrodes UE1, UE2 and UE3 mainly by the first portion P1. In the example of FIG. 2, a large part of the partition 6 corresponds to the first portion P1. The sum of the areas of the second portions P2 is less than the area of the first portion P1.

The second portions P2 may be either conductive or insulated. When the second portions P2 are conductive, the second portions P2 have a resistance which is higher than that of the first portion P1. The second portions P2 are dispersed in the display area DA. For example, the first portion P1 is not completely divided by the second portions P2 and is continuous in the entire display area DA. As another example, in the partition 6, the first portion P1 may be divided by the second portion P2 into a plurality of first portions P1.

In the example of FIG. 2, each second portion P2 is provided next to one of the four sides of each of the rectangular pixel apertures AP1, AP2 and AP3. However, the configuration is not limited to this example. Each second portion P2 may be provided next to two or more of the four sides of each of the pixel apertures AP1, AP2 and AP3.

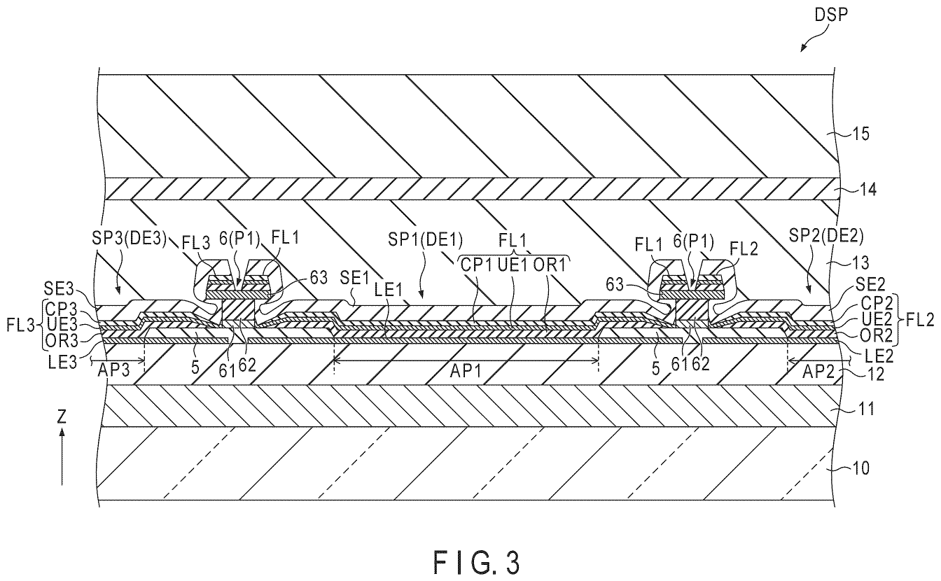

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1.

The circuit layer 11 is covered with an insulating layer 12. The insulating layer 12 functions as a planarization film which planarizes the irregularities formed by the circuit layer 11. Although not shown in the section of FIG. 3, the contact holes CH1, CH2 and CH3 described above are provided in the insulating layer 12.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5.

The partition 6 shown in FIG. 3 corresponds to the first portion P1 shown in FIG. 2. The partition 6 comprises a bottom portion 61 provided on the rib 5, a stem portion 62 provided on the bottom portion 61, and a top portion 63 provided on the stem portion 62. The top portion 63 has a width greater than the widths of the bottom portion 61 and the stem portion 62. By this configuration, in FIG. 3, the both end portions of the top portion 63 protrude relative to the side surfaces of the bottom portion 61 and the stem portion 62. This shape of the partition 6 is called an overhang shape.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3.

In the example of FIG. 3, a cap layer CP1 is provided on the upper electrode UE1. A cap layer CP2 is provided on the upper electrode UE2. A cap layer CP3 is provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a stacked layer body including the organic layer OR1, the upper electrode UE1 and the cap layer CP1 is called a thin film FL1. A stacked layer body including the organic layer OR2, the upper electrode UE2 and the cap layer CP2 is called a thin film FL2. A stacked layer body including the organic layer OR3, the upper electrode UE3 and the cap layer CP3 is called a thin film FL3.

The thin film FL1 is partly located on the top portion 63. This portion is spaced apart from, of the thin film FL1, the portion located under the partition 6 (in other words, the portion which constitutes the display element DE1). Similarly, the thin film FL2 is partly located on the top portion 63. This portion is spaced apart from, of the thin film FL2, the portion located under the partition 6 (in other words, the portion which constitutes the display element DE2). Further, the thin film FL3 is partly located on the top portion 63. This portion is spaced apart from, of the thin film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the thin film FL1 and the partition 6 around subpixel SP1. The sealing layer SE2 continuously covers the thin film FL2 and the partition 6 around subpixel SP2. The sealing layer SE3 continuously covers the thin film FL3 and the partition 6 around subpixel SP3.

In the example of FIG. 3, the thin film FL1 and sealing layer SE1 located on the partition 6 between subpixels SP1 and SP2 are spaced apart from the thin film FL2 and sealing layer SE2 located on this partition 6. The thin film FL1 and sealing layer SE1 located on the partition 6 between subpixels SP1 and SP3 are spaced apart from the thin film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The insulating layer 12 is formed of an organic insulating material. Each of the rib 5 and the sealing layers 14, SE1, SE2 and SE3 can be formed of an inorganic insulating material such as silicon nitride (SiN), silicon oxide (SiO), silicon oxynitride (SiON) or aluminum oxide (Al₂O₃). Each of the rib 5 and the sealing layers 14, SE1, SE2 and SE3 may comprise a single-layer structure formed of one of the inorganic insulating materials, or may comprise a stacked structure in which the layers of two or more types of inorganic insulating materials are stacked. The inorganic insulating materials of the rib 5 and the sealing layers 14, SE1, SE2 and SE3 may be the same as each other or different from each other.

Each of the resin layers 13 and 15 is formed of, for example, a resinous material (organic insulating material) such as epoxy resin or acrylic resin. Each of the lower electrodes LE1, LE2 and LE3 comprises a reflective layer formed of, for example, silver (Ag), and a pair of transparent conductive layers covering the upper and lower surfaces of the reflective layer. Each transparent conductive layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

The cap layers CP1, CP2 and CP3 have refractive indices different from those of the upper electrodes UE1, UE2 and UE3 and the sealing layers SE1, SE2 and SE3. Each of the cap layers CP1, CP2 and CP3 may be formed of a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

The bottom portion 61 can be formed of, for example, a conductive material such as aluminum (Al), titanium (Ti), titanium nitride (TiN), molybdenum (Mo), tungsten (W), a molybdenum-tungsten alloy (MoW), a molybdenum-niobium alloy (MoNb), ITO or IZO. The bottom portion 61 may comprise a single-layer structure formed of one of these materials or may comprise a stacked structure including a plurality of layers formed of different materials.

The stem portion 62 can be formed of, for example, an insulating material such as silicon nitride, silicon oxide or silicon oxynitride. The stem portion 62 may comprise a single-layer structure formed of one of these materials or may comprise a stacked structure including a plurality of layers formed of different materials.

For example, the top portion 63 may be formed of an insulating material such as silicon nitride, silicon oxide or silicon oxynitride, or may be formed of a conductive material such as aluminum, titanium, titanium nitride, molybdenum, tungsten, a molybdenum-tungsten alloy, a molybdenum-niobium alloy (MoNb), ITO or IZO. The top portion 63 may comprise a single-layer structure formed of one of these materials or may comprise a stacked structure including a plurality of layers formed of different materials. When the top portion 63 comprises a stacked structure, the top portion 63 may include a conductive layer formed of a conductive material and an insulating layer formed of an insulating material. In this case, the insulating layer may be provided on the conductive layer, or to the contrary, the conductive layer may be provided on the insulating layer.

The upper electrodes UE1, UE2 and UE3 are in contact with the side surfaces of the bottom portions 61. Common voltage is applied to the bottom portions 61. This common voltage is applied to each of the upper electrodes UE1, UE2 and UE3. Pixel voltage is applied to the lower electrodes LE1, LE2 and LE3 through the pixel circuits 1 provided in subpixels SP1, SP2 and SP3, respectively.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

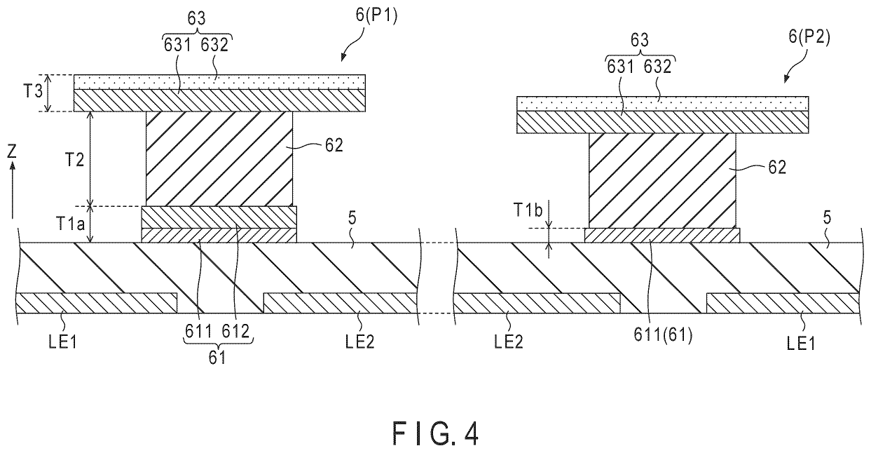

FIG. 4 is a schematic cross-sectional view of the display device DSP along the IV-IV line of FIG. 2 and shows an example of a configuration which could be applied to the first and second portions P2 of the partition 6. In this example, each of the first portion P1 and the second portion P2 comprises a structure in which the bottom portion 61, the stem portion 62 and the top portion 63 are stacked. However, thickness T1a (first thickness) of the bottom portion 61 of the first portion P1 is different from thickness T1b (second thickness) of the bottom portion 61 of the second portion P2.

The bottom portion 61 of the first portion P1 comprises a first bottom layer 611 and a second bottom layer 612 which covers the first bottom layer 611. The bottom portion 61 of the second portion P2 includes the first bottom layer 611 and does not include the second bottom layer 612.

Thus, thickness T1b is less than thickness T1a by the thickness of the second bottom layer 612 (T1a>T1b). The resistance of the second portion P2 is higher than that of the first portion P1 when applying current by reducing the thickness of the conductive bottom portion 61 in the second portion P2 in the above manner. As a result, compared to a case where the second portion P2 is not provided, the resistance is increased in the entire partition 6.

Regarding the stem portion 62 and the top portion 63, the first portion P1 and the second portion P2 comprise the same structure as each other. In the example of FIG. 4, the stem portion 62 comprises a single-layer structure. The top portion 63 comprises a first top layer 631, and a second top layer 632 provided on the first top layer 631.

The materials of the first bottom layer 611 and the second bottom layer 612 could be appropriately selected from the conductive materials described above as the materials of the bottom portion 61. The materials of the first top layer 631 and the second top layer 632 could be appropriately selected from the insulating materials and conductive materials described above as the materials of the top portion 63.

In each of the first portion P1 and the second portion P2, the both end portions of the first top layer 631 and the second top layer 632 protrude relative to the side surfaces of the bottom portion 61 and the stem portion 62 in the width direction of the partition 6. In the example of FIG. 4, the widths of the first bottom layer 611 and the second bottom layer 612 are slightly greater than the width of the stem portion 62. As another example, the widths of the first bottom layer 611 and the second bottom layer 612 may be equal to the width of the stem portion 62.

The stem portion 62 has thickness T2, and the top portion 63 has thickness T3. In the example of FIG. 4, thickness T2 is greater than thicknesses T1a and T1b (T1a, T1b<T2), and thickness T3 is less than thickness T2 (T2>T3). Thicknesses T1a and T3 are, for example, equal to each other. It should be noted that the relationships of thicknesses T1a, T1b, T2 and T3 are not limited to the example shown here.

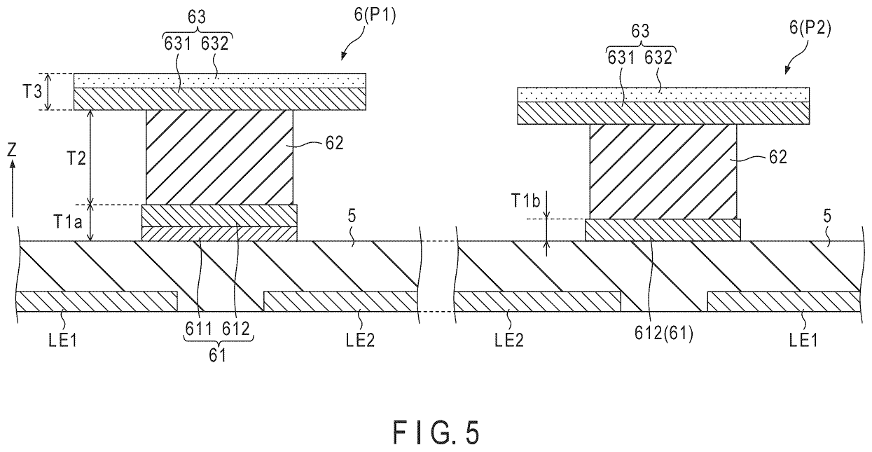

FIG. 5 is a schematic cross-sectional view showing another example of a configuration which could be applied to the first and second portions P1 and P2 of the partition 6. The configuration of the first portion P1 shown in FIG. 5 is the same as the example of FIG. 4.

However, in the example of FIG. 5, the bottom portion 61 of the second portion P2 includes the second bottom layer 612 and does not include the first bottom layer 611. In this case, thickness T1b of the bottom portion 61 of the second portion P2 is less than thickness T1a of the bottom portion 61 of the first portion P1 by the thickness of the first bottom layer 611 (T1a>T1b).

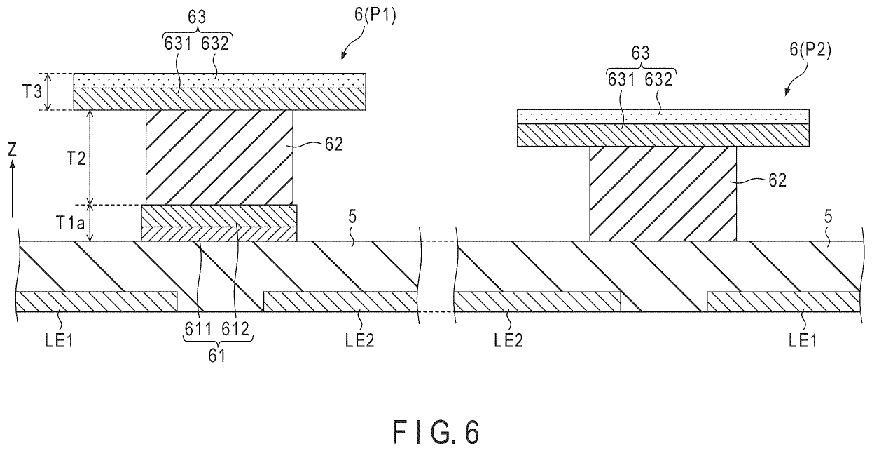

FIG. 6 is a schematic cross-sectional view showing yet another example of a configuration which could be applied to the first and second portions P1 and P2 of the partition 6. The configuration of the first portion P1 shown in FIG. 6 is the same as the examples of FIG. 4 and FIG. 5.

In the example of FIG. 6, the bottom portion 61 is not provided under the stem portion 62 of the second portion P2. In this configuration, the current which flows in the bottom portion 61 does not pass through the second portion P2. As a result, the number of current paths is decreased in the entire partition 6. The resistance in the entire partition 6 is increased compared to a case where the second portion P2 is not provided.

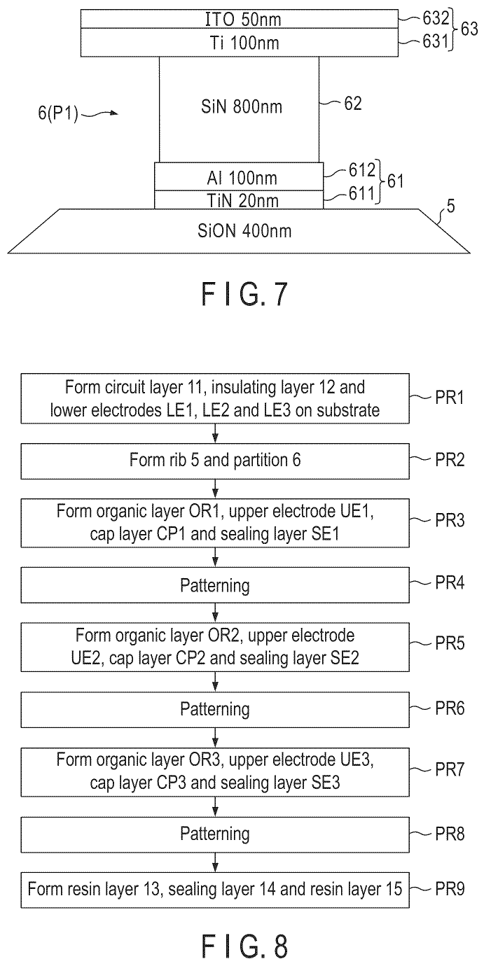

FIG. 7 is a diagram showing an implementation example of the partition 6 and the rib 5. The partition 6 shown in this figure corresponds to the first partition P1 shown in FIG. 4 to FIG. 6. The first bottom layer 611 is formed of titanium nitride. The second bottom layer 612 is formed of aluminum. The stem portion 62 is formed of silicon nitride. The first top layer 631 is formed of titanium. The second top layer 632 is formed of ITO. The rib 5 is formed of silicon oxynitride.

For example, the thickness of the first bottom layer 611 is 20 nm. The thickness of the second bottom layer 612 is thicker than the first bottom layer 611, and is 100 nm. The thickness of the stem portion 62 is 800 nm. The thickness of the first top layer 631 is 100 nm. The thickness of the second top layer 632 is thinner than the first top layer 631, and is 50 nm. The thickness of the rib 5 is, for example, 400 nm.

For the film formation of titanium nitride, aluminum, titanium and ITO, sputtering can be used. For the film formation of silicon nitride and silicon oxynitride, chemical vapor deposition (CVD) can be used.

In a case where the first portion P1 comprises the configuration of FIG. 7, the second portion P2 may not include the second bottom layer 612 as in the case of the example of FIG. 4, or may not include the first bottom layer 611 as in the case of the example of FIG. 5, or neither the first bottom layer 611 nor the second bottom layer 612 may be included in the second portion P2 as in the case of the example of FIG. 6.

It should be noted that the configurations of the partition 6 shown in FIG. 4 to FIG. 7 are merely examples. Each of the bottom portion 61 and the top portion 63 may comprise a single-layer structure or may comprise a stacked structure consisting of three or more layers. The stem portion 62 may comprise a stacked structure consisting of two or more insulating layers.

In a case where the bottom portion 61 comprises a single-layer structure, the configuration of FIG. 6 may be applied such that the second portion P2 does not include the bottom portion 61. In a case where the bottom portion 61 comprises a stacked structure consisting of a plurality of conductive layers, the conductive layers which should be removed in the second portion P2 could be appropriately determined in consideration of the resistance, processability and the like of each conductive layer.

For example, in the bottom portion 61 of the implementation example of FIG. 7, the effect on the resistance of the entire bottom portion 61 is more dominant in the thick second bottom layer 612 formed of aluminum than the thin first bottom layer 611 formed of titanium nitride. The difference in resistance between the first portion P1 and the second portion P2 can be increased by removing the second bottom layer 612 in the second portion P2. In general, the resistance of transparent conductive materials such as ITO and IZO is greater than that of metal materials such as aluminum. In a case where the bottom portion 61 comprises a stacked structure consisting of a layer formed of a transparent conductive material such as ITO or IZO and a layer formed of a metal material, the difference in resistance between the first portion P1 and the second portion P2 can be increased by removing at least the layer formed of the metal material in the second portion P2.

Similarly, in a case where the bottom portion 61 of the first portion P1 comprises a stacked structure consisting of three or more conductive layers, the resistance of the second portion P2 can be increased by removing at least one conductive layer in the bottom portion 61 of the second portion P2.

Now, this specification explains the manufacturing method of the display device DSP, looking at the case where the first and second portions P1 and P2 of the partition 6 comprise the configuration of FIG. 4 as an example.

FIG. 8 is a flowchart showing an example of the manufacturing method of the display device DSP. To manufacture the display device DSP, first, the circuit layer 11, the insulating layer 12 and the lower electrodes LE1, LE2 and LE3 are formed on the substrate 10 (process PR1). Further, the rib 5 and the partition 6 are formed (process PR2).

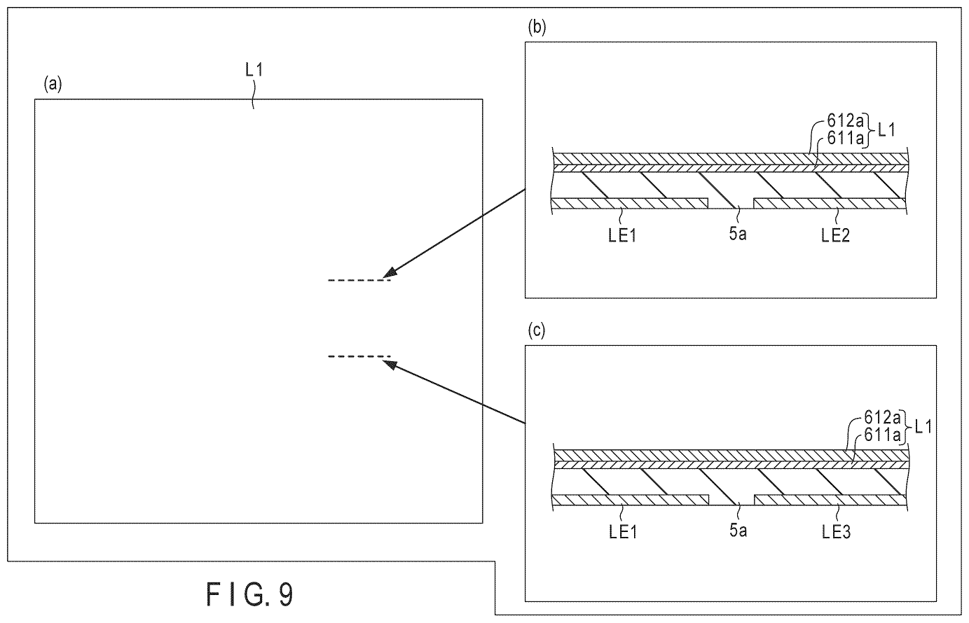

FIG. 9 to FIG. 14 are diagrams showing a series of processes for forming the rib 5 and the partition 6. In these drawings, (a) shows a schematic plan view of part of the display area DA, and (b) shows a schematic cross-sectional view of the area in which the first portion P1 is formed, and (c) shows a schematic cross-sectional view of the area in which the second portion P2 is formed.

In process PR2, first, as shown in FIG. 9, an insulating layer 5a which is processed so as to be the rib 5 is formed. A first layer L1 which is processed so as to be the bottom portion 61 is formed on the insulating layer 5a. As shown in FIG. 9(b) and FIG. 9(c), the first layer L1 includes a first bottom layer 611a, and a second bottom layer 612a which covers the first bottom layer 611a.

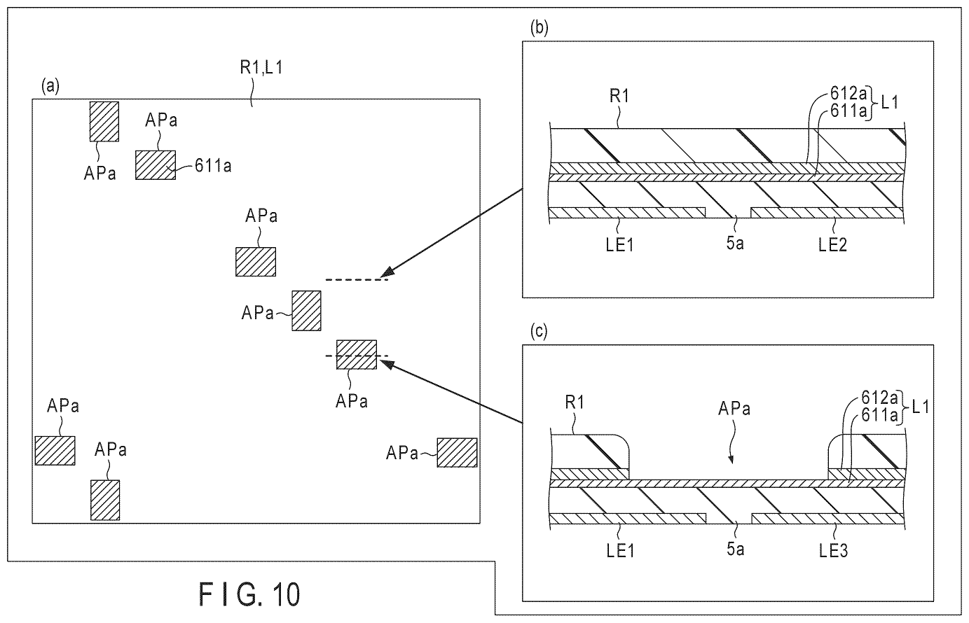

Subsequently, as shown in FIG. 10, a resist R1 is formed on the first layer L1. The resist R1 comprises a plurality of apertures provided at positions corresponding to the second portions P2. By etching using the resist R1 as a mask, the second bottom layer 612a is patterned, and a plurality of apertures APa are formed in the second bottom layer 612a. In FIG. 10(a), a diagonal pattern is added to the first bottom layer 611a exposed through the apertures APa.

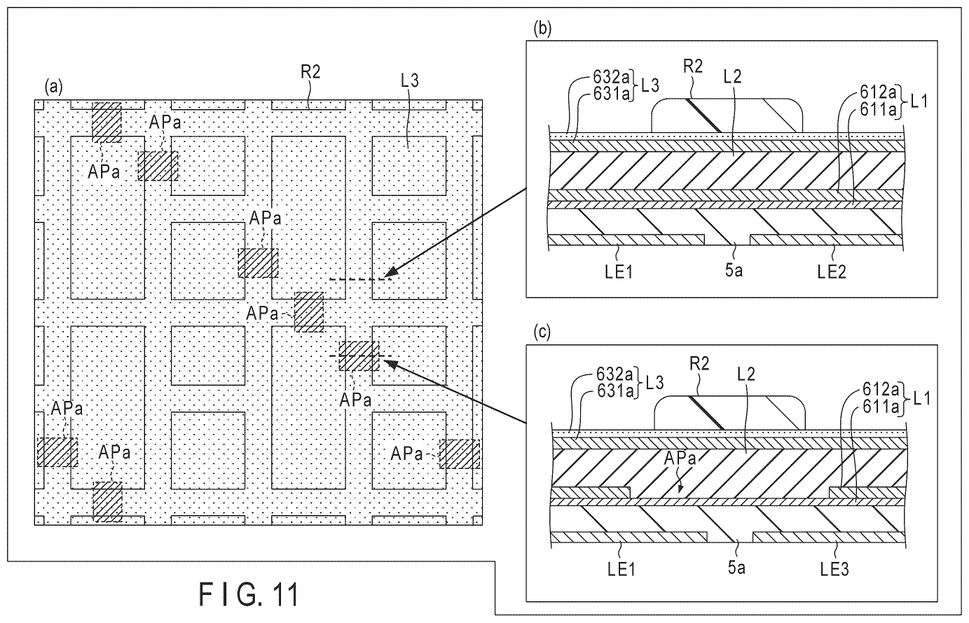

After the process of FIG. 10, the resist R1 is removed. Further, as shown in FIG. 11, a second layer L2 which is processed so as to be the stem portion 62 is formed on the first layer L1. A third layer L3 which is processed so as to be the top portion 63 is formed on the second layer L2. A resist R2 patterned into the planar shape of the partition 6 is formed on the third layer L3. As shown in FIG. 11(a), the width of the resist R2 is less than that of the aperture APa. As shown in FIG. 11(b) and FIG. 11(c), the third layer L3 includes a first top layer 631a, and a second top layer 632a which covers the first top layer 631a.

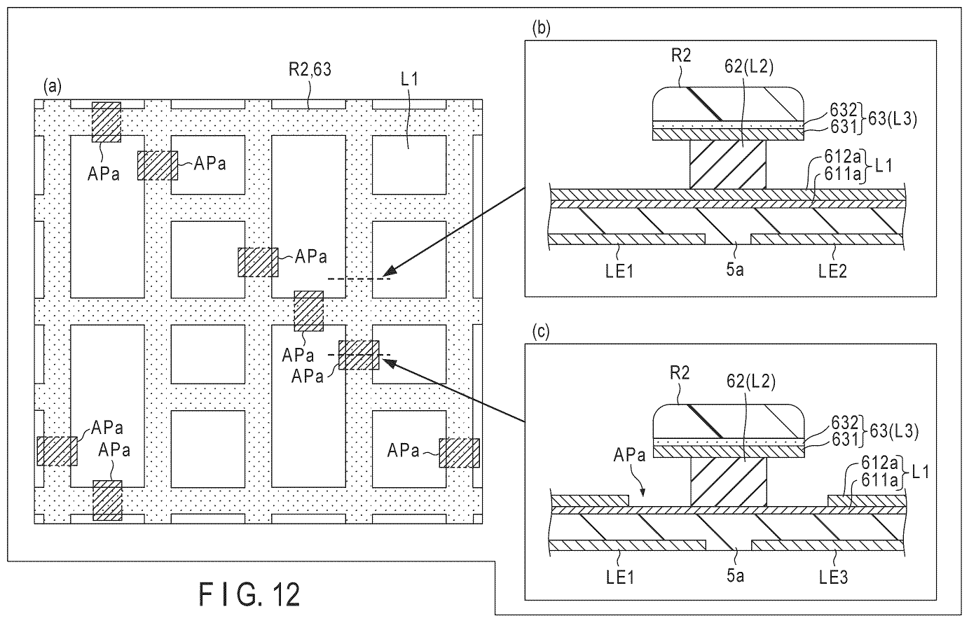

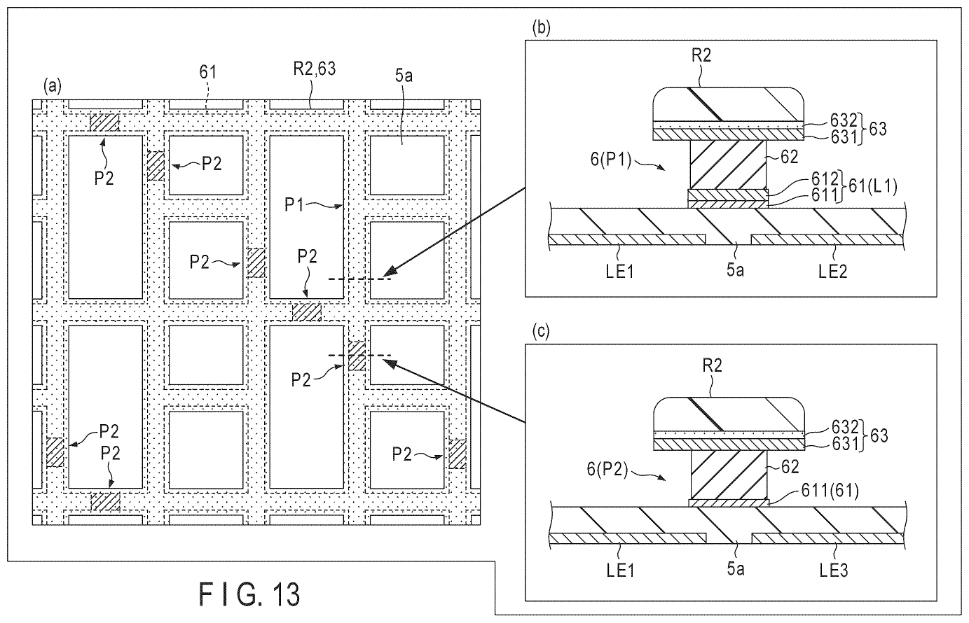

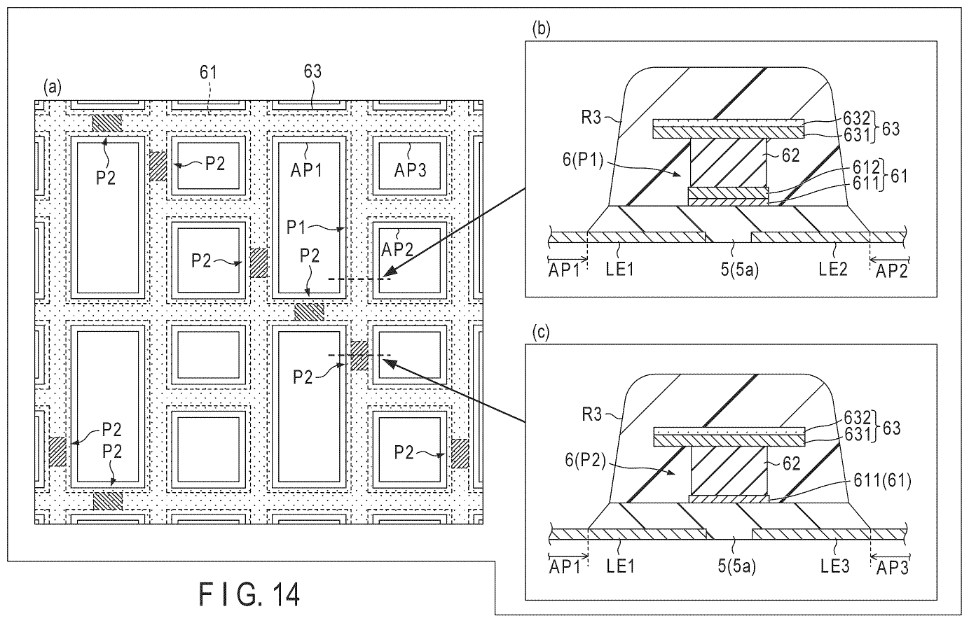

In FIG. 11(a), a dotted pattern is added to the area in which the third layer L3 is present (at this stage, the entire display area DA). This pattern is applied to the following FIG. 12(a), FIG. 13(a) and FIG. 14(a) in a similar manner.

After the process of FIG. 11, as shown in FIG. 12, a first etching process for patterning the third layer L3, and a second etching process for patterning the second layer L2 are performed.

The first etching process includes etching for removing the portion of the second top layer 632a exposed from the resist R2 and etching for removing the portion of the first top layer 631a exposed from the resist R2. By these etching processes, the top portion 63 including the first top layer 631 and the second top layer 632 is formed.

The second etching process includes anisotropic etching for removing the portion of the second layer L2 exposed from the resist R2 and isotropic etching for eroding the side surfaces of the second layer L2 which underwent the anisotropic etching. By these etching processes, the stem portion 62 whose width is less than that of the top portion 63 is formed. As shown in FIG. 12(b), the stem portion 62 is located on the second bottom layer 612a in the area in which the apertures APa are not provided. To the contrary, as shown in FIG. 12(c), the stem portion 62 is located on the first bottom layer 611a in the area in which the aperture APa is provided.

After the process of FIG. 12, as shown in FIG. 13, a third etching process for patterning the first layer L1 is performed. The third etching process includes etching for removing the portion of the second bottom layer 612a exposed from the stem portion 62 and etching for removing the portion of first bottom layer 611a exposed from the stem portion 62.

Through the third etching process, as shown in FIG. 13(b), the first portion P1 comprising the bottom portion 61 including the first bottom layer 611 and the second bottom layer 612 is formed. Further, as shown in FIG. 13(c), the second portion P2 comprising the bottom portion 61 which includes the first bottom layer 611 and does not include the second bottom layer 612 is formed.

In FIG. 13(a), the outer shape of the bottom portion 61 is shown by broken lines. Further, in the bottom portion 61, a diagonal pattern is added to the areas in which the second bottom layer 612 is not provided on the first bottom layer 611.

After the formation of the partition 6 including the first portion P1 and the second portions P2, the resist R2 is removed. Subsequently, as shown in FIG. 14(b) and FIG. 14(c), a resist R3 patterned into the planar shape of the rib 5 is provided. Moreover, the portion of the insulating layer 5a exposed from the resist R3 is removed by etching. By this process, the rib 5 comprising the pixel apertures AP1, AP2 and AP3 is formed. After this etching, the resist R3 is removed.

In the example of FIG. 9 to FIG. 14, the pixel apertures AP1, AP2 and AP3 of the rib 5 are formed after the formation of the partition 6. As another example, the partition 6 may be formed after the formation of the pixel apertures AP1, AP2 and AP3.

After the formation of the rib 5 and the partition 6, processes PR3 to PR8 for forming the display elements DE1, DE2 and DE3 are performed (see FIG. 8). In the present embodiment, this specification assumes a case where the display element DE1 is formed firstly, and the display element DE2 is formed secondly, and the display element DE3 is formed lastly. It should be noted that the formation order of the display elements DE1, DE2 and DE3 is not limited to this example.

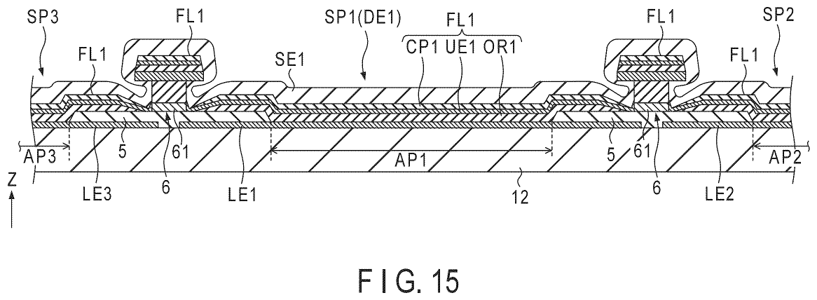

FIG. 15 to FIG. 20 are schematic cross-sectional views showing a series of processes for forming the display elements DE1, DE2 and DE3. To form the display element DE1, first, as shown in FIG. 15, the organic layer OR1 which covers the lower electrode LE1 through the pixel aperture AP1, the upper electrode UE1 which covers the organic layer OR1 and is in contact with the side surfaces of the bottom portions 61 and the cap layer CP1 which covers the upper electrode UE1 are formed in order by vapor deposition, and further, the sealing layer SE1 which continuously covers the cap layer CP1 and the partition 6 is formed by CVD (process PR3).

The thin film FL1 including the organic layer OR1, the upper electrode UE1 and the cap layer CP1 is formed in at least the entire display area DA, is provided in subpixels SP2 and SP3 as well as subpixel SP1 and is also provided on the partition 6. The thin film FL1 is divided by the partition 6 having an overhang shape. The sealing layer SE1 is formed in the entire display area DA and continuously covers the thin film FL1 and the partition 6 without being divided by the partition 6.

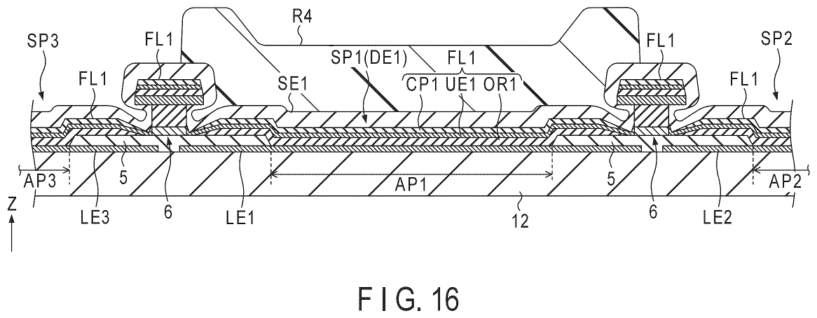

After process PR3, the thin film FL1 and the sealing layer SE are patterned (process PR4). In this patterning, as shown in FIG. 16, a resist R4 is provided on the sealing layer SE1. The resist R4 covers subpixel SP1 and part of the partition 6 around the subpixel.

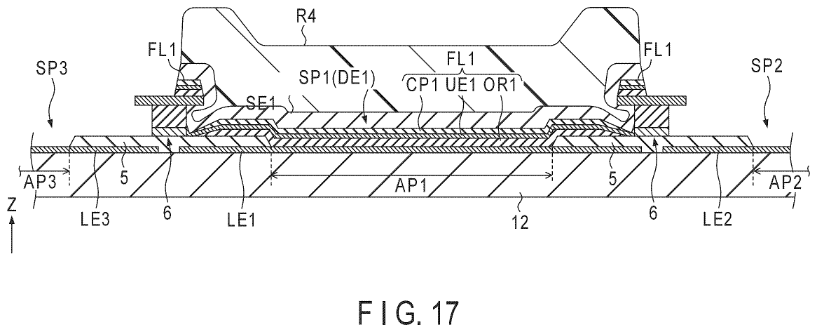

Subsequently, as shown in FIG. 17, the portions of the thin film FL1 and the sealing layer SE1 exposed from the resist R4 are removed by etching using the resist R4 as a mask. For example, this etching includes wet etching and dry etching processes which are performed in order for the sealing layer SE1, the cap layer CP1, the upper electrode UE1 and the organic layer OR1.

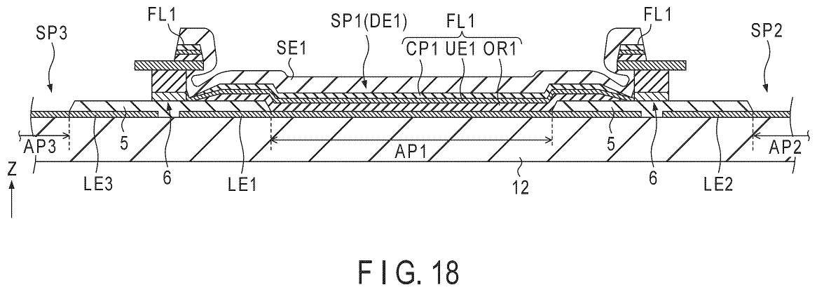

After the process shown in FIG. 17, the resist R4 is removed. This process allows the acquisition of the following substrate. As shown in FIG. 18, in the substrate, the display element DE1 and the sealing layer SE1 are formed in subpixel SP1, and neither a display element nor a sealing layer is formed in subpixel SP2 or subpixel SP3.

The display element DE2 is formed by a procedure similar to that of the display element DE1. Specifically, after process PR4, the organic layer OR2 which covers the lower electrode LE2 through the pixel aperture AP2, the upper electrode UE2 which covers the organic layer OR2 and the cap layer CP2 which covers the upper electrode UE2 are formed in order by vapor deposition, and further, the sealing layer SE2 which continuously covers the cap layer CP2 and the partition 6 is formed by CVD (process PR5).

The thin film FL2 including the organic layer OR2, the upper electrode UE2 and the cap layer CP2 is formed in at least the entire display area DA, is provided in subpixels SP1 and SP3 as well as subpixel SP2 and is also provided on the partition 6. The thin film FL2 is divided by the partition 6 having an overhang shape. The sealing layer SE2 is formed in the entire display area DA and continuously covers the thin film FL2 and the partition 6 without being divided by the partition 6.

After process PR5, the thin film FL2 and the sealing layer SE2 are patterned by wet etching and dry etching (process PR6). The flow of this patterning is similar to that of process PR4.

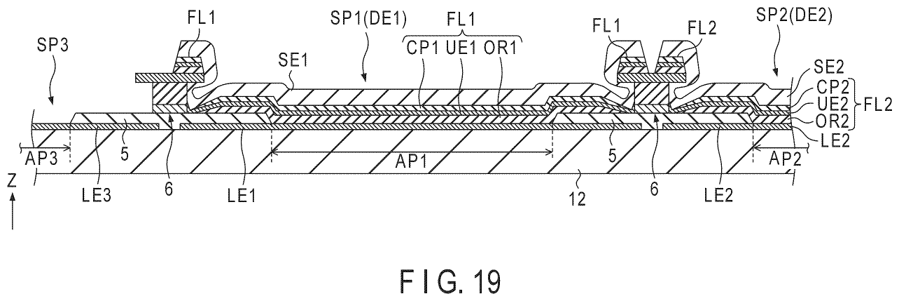

Process PR6 allows the acquisition of the following substrate. As shown in FIG. 19, in the substrate, the display element DE1 and the sealing layer SE1 are formed in subpixel SP1, and the display element DE2 and the sealing layer SE2 are formed in subpixel SP2, and neither a display element nor a sealing layer is formed in subpixel SP3.

The display element DE3 is formed by a procedure similar to the procedures of the display elements DE1 and DE2. Specifically, after process PR6, the organic layer OR3 which covers the lower electrode LE3 through the pixel aperture AP3, the upper electrode UE3 which covers the organic layer OR3 and the cap layer CP3 which covers the upper electrode UE3 are formed in order by vapor deposition, and further, the sealing layer SE3 which continuously covers the cap layer CP3 and the partition 6 is formed by CVD (process PR7).

The thin film FL3 including the organic layer OR3, the upper electrode UE3 and the cap layer CP3 is formed in at least the entire display area DA, is provided in subpixels SP1 and SP2 as well as subpixel SP3 and is also provided on the partition 6. The thin film FL3 is divided by the partition 6 having an overhang shape. The sealing layer SE3 is formed in the entire display area DA and continuously covers the thin film FL3 and the partition 6 without being divided by the partition 6.

After process PR7, the thin film FL3 and the sealing layer SE3 are patterned by wet etching and dry etching (process PR8). The flow of this patterning is similar to that of process PR4.

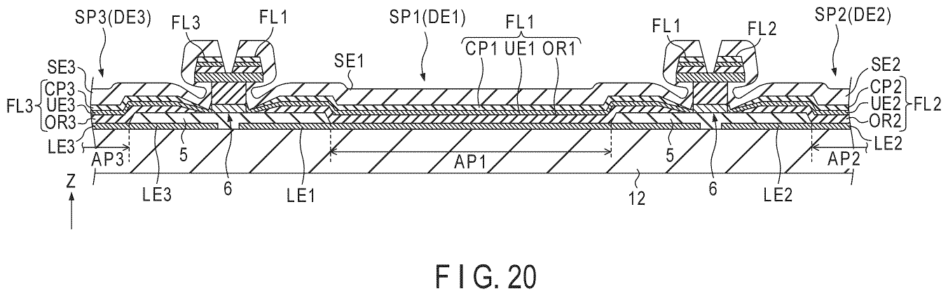

Process PR8 allows the acquisition of the following substrate. As shown in FIG. 20, in the substrate, the display element DE1 and the sealing layer SE1 are formed in subpixel SP1, and the display element DE2 and the sealing layer SE2 are formed in subpixel SP2, and the display element DE3 and the sealing layer SE3 are formed in subpixel SP3.

After the display elements DE1, DE2 and DE3 and the sealing layers SE1, SE2 and SE3 are formed, the resin layer 13, sealing layer 14 and resin layer 15 shown in FIG. 3 are formed in order (process PR9). By this process, the display device DSP is completed.

In the manufacturing method of the display device DSP of the embodiment explained above, the thin films FL1, FL2 and FL3 formed by vapor deposition are divided by the partition 6 having an overhang shape. Further, by covering these divided thin films FL1, FL2 and FL3 with the sealing layers SE1, SE2 and SE3, respectively, the display elements DE1, DE2 and DE3 which are individually sealed can be obtained. The partition 6 also functions as lines which supply electricity to the upper electrodes UE1, UE2 and UE3.

To satisfactorily divide the thin films FL1, FL2 and FL3, the thicknesses of the bottom portion 61 and the stem portion 62 of the partition 6 and the protrusion length of the top portion 63 from each side surface of the stem portion 62 need to be great. If the entire bottom portion 61 and the entire stem portion 62 are formed of conductive materials, and they are thick, the resistance of the partition 6 is considerably decreased.

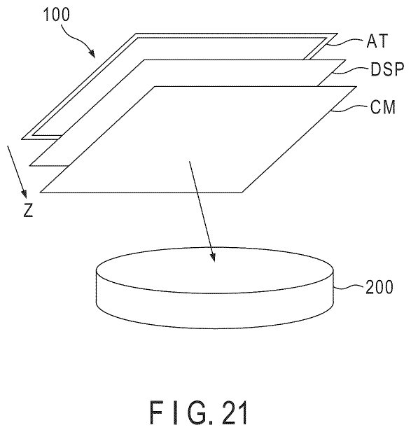

The considerable reduction in the resistance of the partition 6 may not be desirable depending on the use situation of the display device DSP. FIG. 21 is a pattern diagram showing an example of such a situation. In this figure, the display device DSP is mounted on an electronic device 100. The electronic device 100 is, for example, a mobile terminal such as a smartphone or a wearable terminal such as a smartwatch.

The electronic device 100 comprises a cover member CM provided on the display surface side of the display device DSP (the upper surface side of the resin layer 15 shown in FIG. 3), and an antenna AT provided on the rear surface side of the display device DSP (the lower surface side of the substrate 10 shown in FIG. 3). The cover member CM is formed of, for example, glass. The antenna AT transmits and receives radio waves for short-range wireless communication (near field communication [NFC]).

When the electronic device 100 comprising this configuration performs short-range wireless communication with a reader 200, the electronic device 100 is held over the reader 200 such that, for example, the cover member CM faces the reader 200. At this time, the display device DSP is interposed between the antenna AT and the reader 200. In this case, if the resistance of the partition 6 is excessively low, there is a possibility that the partition 6 affects the sensitivity of the communication between the antenna AT and the reader 200.

In the embodiment, the partition 6 comprises the conductive bottom portion 61 and the insulating stem portion 62. In this configuration, the resistance of the partition 6 can be increased compared to a case where the entire partition 6 or the entire part of the portion excluding the top portion 63 from the partition 6 is formed of a conductive material.

Further, in the embodiment, the resistance of the partition 6 is increased by providing the second portions P2 at a plurality of positions in the partition 6. As a result, when the display device DSP is used in the situation shown in FIG. 21, the sensitivity of short-range wireless communication can be satisfactorily maintained.

The second portions P2 have an overhang shape similar to that of the first portion P1. Thus, similarly, the thin films FL1, FL2 and FL3 can be satisfactorily divided near the second portions P2.

The resistance of the partition 6 can be adjusted so as to be an appropriate value by thickness T1a of the bottom portion 61 shown in, for example, FIG. 4 to FIG. 6. In other words, when the resistance of the partition 6 should be increased, thickness T1a should be less. When the resistance should be reduced, thickness T1a should be great.

Moreover, the resistance of the partition 6 can be adjusted by the number, widths and positions of the second portions P2, thickness T1b of the bottom portion 61 in the second portions P2, etc. Thus, a desired resistance can be realized in the partition 6 based on the performance required for the display device DSP by adjusting various parameters. Further, when the height of the partition 6 is adjusted mainly by thickness T2 of the stem portion 62, the height of the partition 6 can be controlled independently from the resistance.

In the embodiment, a case where the entire stem portion 62 is insulated is shown as an example. However, the stem portion 62 may include a layer formed of a transparent conductive material such as ITO or IZO. Even in this case, the resistance of the partition 6 can be adjusted by providing the second portion P2 in the bottom portion 61.

### Second Embodiment

A second embodiment is explained.

Configurations similar to those of the first embodiment can be applied to configurations which are not particularly referred to.

In some cases, various types of photoreceivers which detect the light which enters a display area DA may be provided on the rear surface side of a display device DSP (the lower surface side of the substrate 10 shown in FIG. 3). As examples of the photoreceivers, a dimming sensor (environmental light sensor) which detects environmental light and a camera are considered.

In the display device DSP comprising the configuration disclosed in the first embodiment, if the partition 6 has light-shielding properties, a large part of the display area DA is shielded from light by the partition 6 and the lower electrodes LE1, LE2 and LE3. In this case, the detection of light by the photoreceivers described above is disturbed. To solve this problem, this embodiment discloses a configuration for increasing translucency in a display area DA.

In a manner similar to that of the first embodiment, a partition 6 comprises a first portion P1 and a plurality of second portions P2. In this embodiment, the first portion P1 has light-shielding properties, and the second portions P2 have translucency. Hereinafter, a configuration for realizing this partition 6 is exemplarily shown.

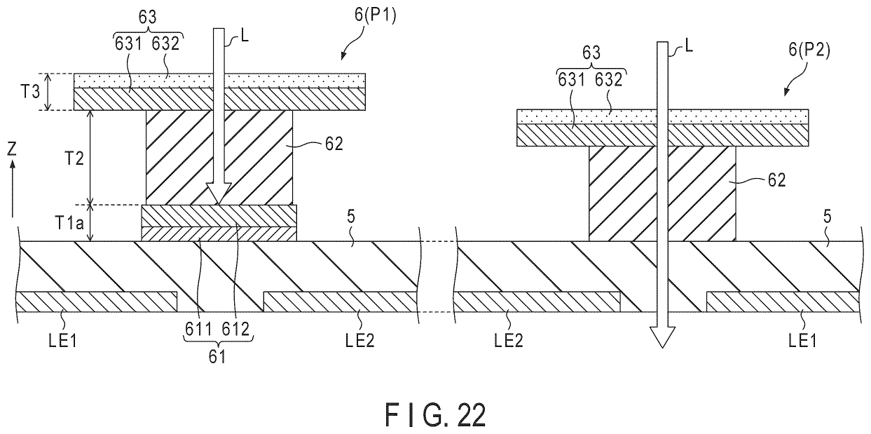

FIG. 22 is a schematic cross-sectional view showing an example of the partition 6 according to the embodiment. In the example of FIG. 22, the first portion P1 comprises a structure in which a bottom portion 61, a stem portion 62 and a top portion 63 are stacked.

In a manner similar to that of the examples of FIG. 4 to FIG. 6, the bottom portion 61 of the first portion P1 comprises a first bottom layer 611 and a second bottom layer 612. In each of the first portion P1 and the second portion P2, the top portion 63 comprises a first top layer 631 and a second top layer 632, and the stem portion 62 comprises a single-layer structure.

In this embodiment, the stem portion 62 and the top portion 63 have translucency. A rib 5, and the substrate 10, insulating layer 12, resin layers 13 and 15 and sealing layer 14 shown in FIG. 3 also have translucency. A circuit layer 11 could include a metal line having light-shielding properties. However, the circuit layer 11 has translucency in an area in which such a line is not provided.

The stem portion 62 can be formed of, in a manner similar to that of the first embodiment, an insulating material such as silicon nitride, silicon oxide or silicon oxynitride. The stem portion 62 may include a layer formed of a transparent conductive material such as ITO or IZO.

For example, each of the first top layer 631 and the second top layer 632 may be formed of an insulating material such as silicon nitride, silicon oxide or silicon oxynitride, or may be formed of a transparent conductive material such as ITO or IZO.

For example, both the first bottom layer 611 and the second bottom layer 612 are formed of a metal material. In this case, the bottom portion 61 has light-shielding properties. For the metal materials which could be used for the first bottom layer 611 and the second bottom layer 612, for example, aluminum, titanium, titanium nitride, molybdenum, tungsten, a molybdenum-tungsten alloy and a molybdenum-niobium alloy are considered.

In the example of FIG. 22, the second portion P2 does not include the bottom portion 61. In other words, both the first bottom layer 611 and the second bottom layer 612 having light-shielding properties are removed from the second portion P2.

In a case where the partition 6 comprises this configuration, light L such as external light which enters the first portion P1 passes through the top portion 63 and the stem portion 62. However, such light L is blocked by the bottom portion 61. To the contrary, in the second portion P2, light L is not blocked by the partition 6. At least part of light L which passed through the partition 6 in this manner passes through the rib 5, the gaps between the lower electrodes LE1, LE2 and LE3 and the like, and is emitted to the lower side of the display device DSP.

In FIG. 22, a case where both the first bottom layer 611 and the second bottom layer 612 have light-shielding properties is assumed. However, the configuration is not limited to this example. For example, one of the first bottom layer 611 and the second bottom layer 612 may be formed of a transparent conductive material such as ITO or IZO and thus may have translucency, and the other one may be formed of a metal material and thus may have light-shielding properties. In this case, in a manner similar to that of the configurations shown in FIG. 4 and FIG. 5, the second portion P2 may include, of the first bottom layer 611 and the second bottom layer 612, the layer having translucency, and may not include the other layer having light-shielding properties.

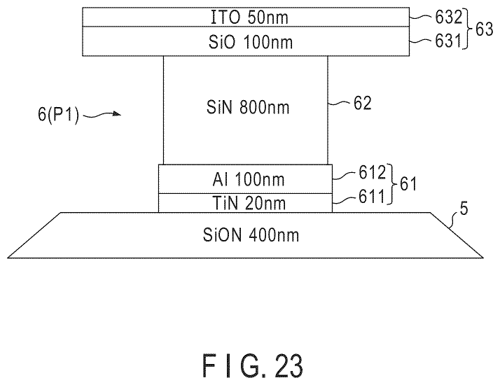

FIG. 23 is a diagram showing an implementation example of the partition 6 and the rib 5 according to the embodiment. The partition 6 shown in this figure corresponds to the first partition P1 shown in FIG. 22. The first bottom layer 611 is formed of titanium nitride. The second bottom layer 612 is formed of aluminum. The stem portion 62 is formed of silicon nitride. The first top layer 631 is formed of silicon oxide. The second top layer 632 is formed of ITO. The rib 5 is formed of silicon oxynitride.

For example, the thickness of the first bottom layer 611 is 20 nm. The thickness of the second bottom layer 612 is thicker than the first bottom layer 611, and is 100 nm. The thickness of the stem portion 62 is 800 nm. The thickness of the first top layer 631 is 100 nm. The thickness of the second top layer 632 is thinner than the first top layer 631, and is 50 nm. The thickness of the rib 5 is, for example, 400 nm.

For the film formation of titanium nitride, aluminum and ITO, sputtering can be used. For the film formation of silicon nitride, silicon oxide and silicon oxynitride, CVD can be used.

The configuration of the partition 6 shown in FIG. 22 and FIG. 23 is merely an example. Each of the bottom portion 61 and the top portion 63 may comprise a single-layer structure or may comprise a stacked structure consisting of three or more layers. The stem portion 62 may comprise a stacked structure consisting of two or more layers.

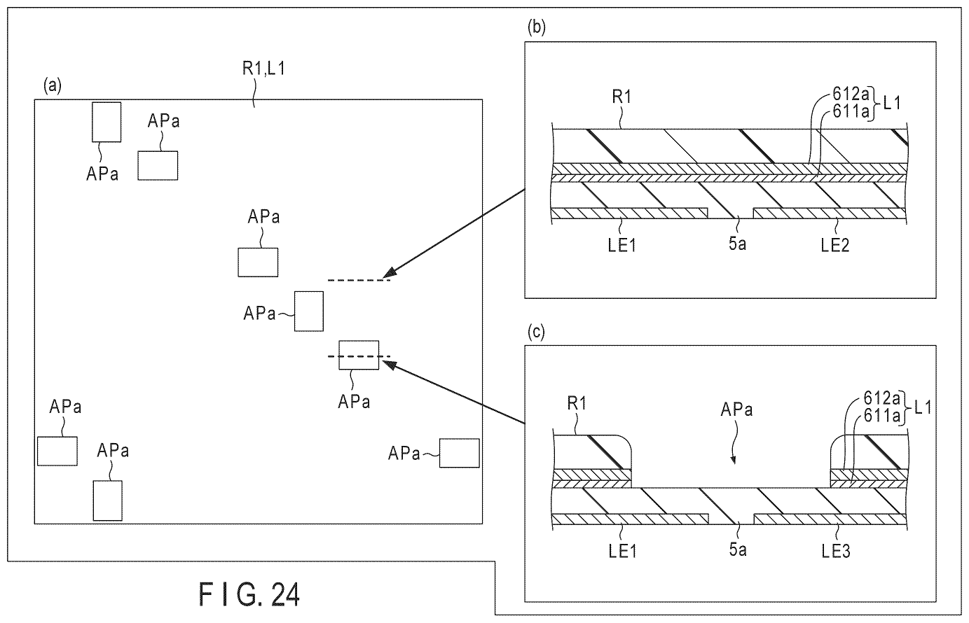

Now, this specification explains the manufacturing process of the partition 6 in the present embodiment, looking at a case where the first and second portions P1 and P2 of the partition 6 comprise the configuration of FIG. 22 as an example. FIG. 24 to FIG. 28 are diagrams showing a series of processes for forming the rib 5 and the partition 6.

To form the partition 6, firstly, in a manner similar to that of the process of FIG. 9 in the first embodiment, an insulating layer 5a and a first layer L1 including a first bottom layer 611a and a second bottom layer 612a are formed.

Subsequently, in a manner similar to that of the process of FIG. 10 in the first embodiment, a resist R1 is formed on the first layer L1, and a plurality of apertures APa are formed in the first layer L1. It should be noted that, in this embodiment, as shown in FIG. 24, the apertures APa penetrate both the first bottom layer 611a and the second bottom layer 612a.

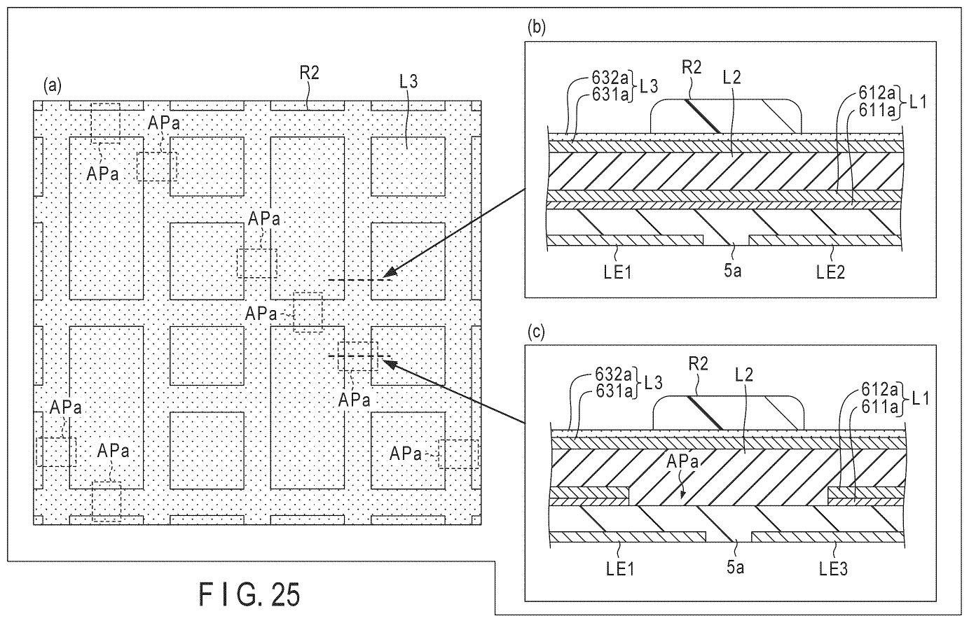

After the process of FIG. 24, the resist R1 is removed. Further, as shown in FIG. 25, a second layer L2, a third layer L3 including a first top layer 631a and a second top layer 632a and a resist R2 are formed.

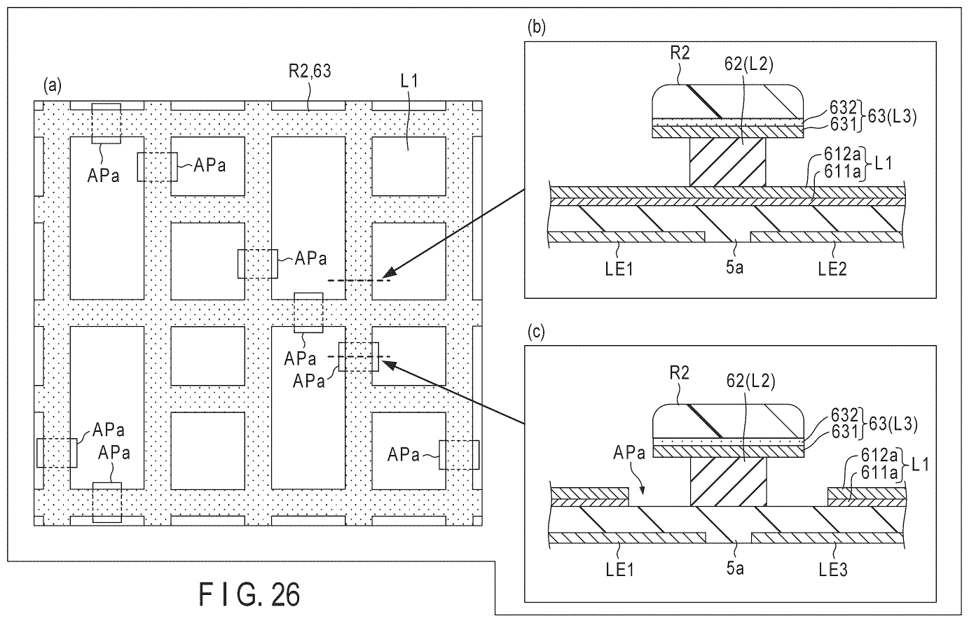

After the process of FIG. 25, as shown in FIG. 26, a first etching process for patterning the third layer L3 and a second etching process for patterning the second layer L2 are performed. These etching processes are similar to those of the example of FIG. 12 in the first embodiment. Thus, by these etching processes, the top portion 63 including the first top layer 631 and the second top layer 632 and the stem portion 62 having a width less than that of the top portion 63 are formed.

As shown in FIG. 26(b), the stem portion 62 is located on the second bottom layer 612a in the area in which the apertures APa are not provided. To the contrary, as shown in FIG. 26(c), the stem portion 62 is located on the insulating layer 5a in the area in which the aperture APa is provided.

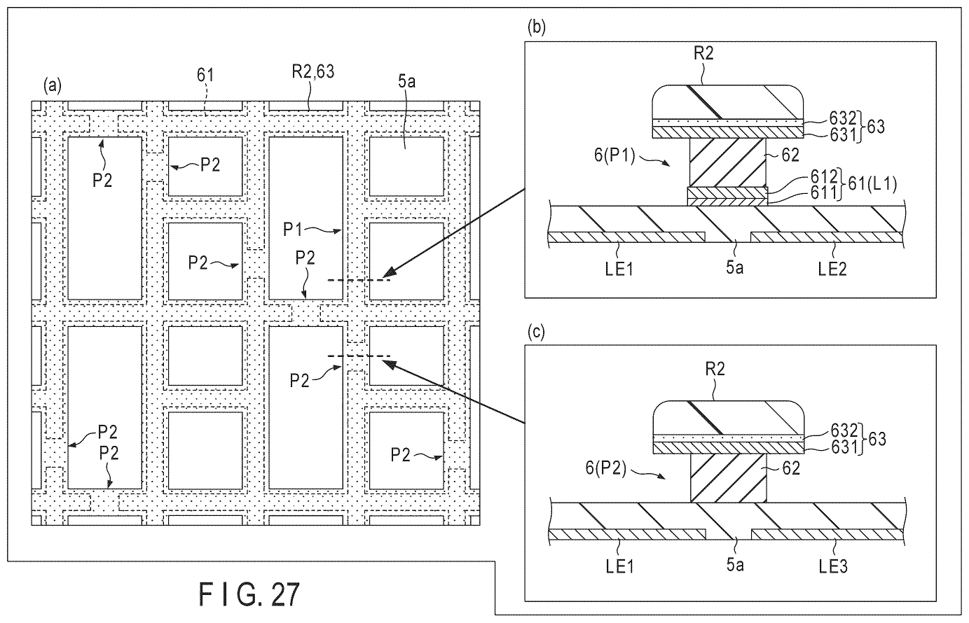

After the process of FIG. 26, as shown in FIG. 27, a third etching process for patterning the first layer L1 is performed. The third etching process is similar to that of the example of FIG. 13 in the first embodiment. Thus, through the third etching process, as shown in FIG. 27(b), the first portion P1 comprising the bottom portion 61 including the first bottom layer 611 and the second bottom layer 612 is formed. Further, as shown in FIG. 27(c), the second portion P2 which does not comprise the bottom portion 61 is formed.

In FIG. 27(a), the outer shape of the bottom portion 61 is shown by broken lines. In this embodiment, the bottom portion 61 is disconnected in the second portions P2.

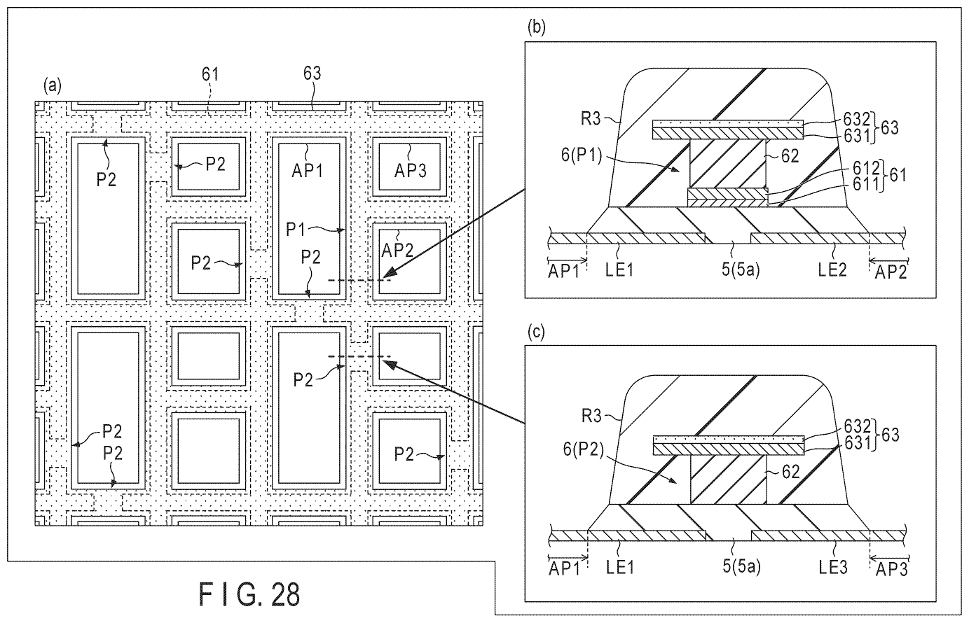

After the formation of the partition 6 including the first portion P1 and the second portions P2, the resist R2 is removed. Subsequently, as shown in FIG. 28(b) and FIG. 28(c), a resist R3 which is similar to that of the process of FIG. 14 in the first embodiment is provided. By etching using the resist R3 as a mask, the rib 5 comprising pixel apertures AP1, AP2 and AP3 is formed. After this etching, the resist R3 is removed.

In the example of FIG. 24 to FIG. 28, the pixel apertures AP1, AP2 and AP3 of the rib 5 are formed after the formation of the partition 6. As another example, the partition 6 may be formed after the formation of the pixel apertures AP1, AP2 and AP3.

In this embodiment, as the second portions P2 of the partition 6 have translucency, the transmittance in the display area DA can be increased. This configuration allows the increase in the detection accuracy by photoreceivers when, for example, the photoreceivers are provided on the rear surface side of the display device DSP.

The second portions P2 have an overhang shape similar to that of the first portion P1. Thus, similarly, thin films FL1, FL2 and FL3 can be satisfactorily divided near the second portions P2. Further, in a manner similar to that of the first embodiment, the resistance of the partition 6 can be adjusted by the second portions P2.

### Third Embodiment

A third embodiment is explained.

Configurations similar to those of the first and second embodiments can be applied to configurations which are not particularly referred to.

In this embodiment, a partition 6 comprises a uniform configuration in which the partition 6 is not distinguished as a first portion P1 or a second portion P2. Further, the partition 6 is formed of a material having translucency as a whole.

For example, the partition 6 comprises a conductive bottom portion 61, an insulating stem portion 62 and a top portion 63. All of these bottom portion 61, stem portion 62 and top portion 63 have translucency.

In the embodiment, the bottom portion 61 comprises a single-layer structure of a transparent conductive material such as ITO or IZO or a stacked structure formed of these materials. The stem portion 62 comprises, for example, a single-layer structure of an insulating material such as silicon nitride, silicon oxide or silicon oxynitride or a stacked structure formed of these materials. The top portion 63 comprises, for example, a single-layer structure of a material such as silicon nitride, silicon oxide, silicon oxynitride, ITO or IZO or a stacked structure formed of these materials.

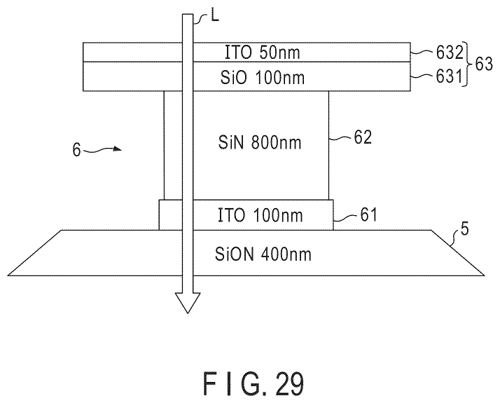

FIG. 29 is a diagram showing an implementation example of the partition 6 and a rib 5 according to the embodiment. In this example, the bottom portion 61 comprises a single-layer structure formed of ITO, and the stem portion 62 comprises a single-layer structure formed of silicon nitride. The top portion 63 comprises a first top layer 631 formed of silicon oxide, and a second top layer 632 formed of ITO. The rib 5 is formed of silicon oxynitride.

For example, the thickness of the bottom portion 61 is 100 nm. The thickness of the stem portion 62 is 800 nm. The thickness of a first top layer 631 is 100 nm. The thickness of a second top layer 632 is thinner than the first top layer 631, and is 50 nm. The thickness of the rib 5 is, for example, 400 nm.

In a case where the partition 6 comprises this configuration, light L such as external light which enters the partition 6 passes through the top portion 63, the stem portion 62 and the bottom portion 61. Further, at least part of light L which passed through the partition 6 in this manner also passes through the rib 5, etc., and is emitted to the lower side of the display device DSP.

The partition 6 of the embodiment can be formed by, for example, substantially the same process as the process shown in FIG. 9 to FIG. 14. However, in the present embodiment, the process of providing apertures APa in a first layer L1 (see FIG. 10) is omitted.

In the present embodiment, as the partition 6 has translucency as a whole, the transmittance in a display area DA can be considerably increased. This configuration allows the increase in the detection accuracy by photoreceivers when, for example, the photoreceivers are provided on the rear surface side of the display device DSP as explained in the second embodiment.

The first to third embodiments can provide a display device DSP in which the interconnection structure for supplying electricity to the upper electrodes UE1, UE2 and UE3, in other words, the structure of the partition 6, is improved in terms of at least the resistance and translucency.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a lower electrode;
a rib having a pixel aperture which overlaps the lower electrode;
a partition comprising a conductive bottom portion provided on the rib, an insulating stem portion provided on the bottom portion, and a top portion provided on the stem portion and protruding from a side surface of the stem portion;
an organic layer which covers the lower electrode through the pixel aperture and emits light based on application of voltage; and
an upper electrode which covers the organic layer and is in contact with the bottom portion, wherein
the partition includes:
a first portion in which the bottom portion having a first thickness, the stem portion and the top portion are stacked; and
a second portion in which the bottom portion having a second thickness less than the first thickness, the stem portion and the top portion are stacked.

2. The display device of claim 1, wherein
the bottom portion comprises a first bottom layer, and a second bottom layer which covers the first bottom layer,
the first portion includes the first bottom layer and the second bottom layer, and
the second portion includes one of the first bottom layer and the second bottom layer and does not include the other one.

3. The display device of claim 2, wherein
the one of the first bottom layer and the second bottom layer, the rib, the stem portion and the top portion have translucency, and
the other one of the first bottom layer and the second bottom layer has light-shielding properties.

4. The display device of claim 2, wherein
the first bottom layer and the second bottom layer are thinner than the stem portion.

5. The display device of claim 2, wherein
each of the first bottom layer and the second bottom layer is formed of a metal material.

6. The display device of claim 2, wherein
the stem portion is formed of at least one of silicon nitride, silicon oxide and silicon oxynitride.

7. The display device of claim 1, further comprising a sealing layer which continuously covers the partition and a thin film including the organic layer and the upper electrode.

8. The display device of claim 7, further comprising a cap layer which has a refractive index different from a refractive index of the sealing layer and is provided between the upper electrode and the sealing layer.

9. A display device comprising:
a lower electrode;
a rib having a pixel aperture which overlaps the lower electrode;
a partition comprising a conductive bottom portion provided on the rib, an insulating stem portion provided on the bottom portion, and a top portion provided on the stem portion and protruding from a side surface of the stem portion;
an organic layer which covers the lower electrode through the pixel aperture and emits light based on application of voltage; and
an upper electrode which covers the organic layer and is in contact with the bottom portion, wherein
the partition includes:
a first portion in which the bottom portion, the stem portion and the top portion are stacked; and
a second portion in which the stem portion and the top portion are stacked, and the bottom portion is not provided under the stem portion.

10. The display device of claim 9, wherein
the rib, the stem portion and the top portion have translucency, and
the bottom portion has light-shielding properties.

11. The display device of claim 9, wherein
the bottom portion is thinner than the stem portion.

12. The display device of claim 9, wherein
the bottom portion is formed of a metal material.

13. The display device of claim 9, wherein
the stem portion is formed of at least one of silicon nitride, silicon oxide and silicon oxynitride.

14. The display device of claim 9, further comprising a sealing layer which continuously covers the partition and a thin film including the organic layer and the upper electrode.

15. The display device of claim 14, further comprising a cap layer which has a refractive index different from a refractive index of the sealing layer and is provided between the upper electrode and the sealing layer.

16. A display device comprising:
a lower electrode;
a rib having a pixel aperture which overlaps the lower electrode;
a partition comprising a conductive bottom portion provided on the rib, an insulating stem portion provided on the bottom portion, and a top portion provided on the stem portion and protruding from a side surface of the stem portion;
an organic layer which covers the lower electrode through the pixel aperture and emits light based on application of voltage; and
an upper electrode which covers the organic layer and is in contact with the bottom portion, wherein
the rib, the bottom portion, the stem portion and the top portion have translucency.

17. The display device of claim 16, wherein
the bottom portion is formed of ITO.

18. The display device of claim 16, wherein
the stem portion is formed of at least one of silicon nitride, silicon oxide and silicon oxynitride.

19. The display device of claim 16, further comprising a sealing layer which continuously covers the partition and a thin film including the organic layer and the upper electrode.

20. The display device of claim 19, further comprising a cap layer which has a refractive index different from a refractive index of the sealing layer and is provided between the upper electrode and the sealing layer.
